(19) United States
(12) Patent Application Publication
(10) Pub. No.: US 2026/0140172 A1
(43) Pub. Date: May 21, 2026

(54) FAST WAFER TEST FOR EVENT-BASED VISION SENSOR

(71) Applicant: OMNIVISION TECHNOLOGIES, INC., Santa Clara, CA (US)

(72) Inventors: Andreas Suess, San Jose, CA (US); Menghan Guo, Shanghai (CN)

(21) Appl. No.: 18/952,759

(22) Filed: Nov. 19, 2024

(51) Int. Cl. G01R 31/317

(52) U.S. Cl. CPC G01R 31/31703; G01R 31/31713

(57) ABSTRACT

A method for wafer testing an event-based vision sensor (EVS), the EVS sensor comprising a photodiode, a logarithmic amplifier configured to generate an amplified signal in response to voltage received by the photodiode, a first buffer, and a bitline (BL), the method including determining a performance of the logarithmic amplifier, where determining the performance includes irradiating a pixel array by sweeping irradiance, feeding an output of the pixel array into the BL, probing one or more output of the BL with an analog-to-digital converter (ADC), and monitoring the one or more outputs of the BL, wherein the performance is determined based upon the one or more outputs of the BL.

### BACKGROUND INFORMATION

### Field of the Disclosure

This disclosure relates generally to the design of image sensors (or event-based vision sensors), and in particular, relates to methods of testing the performance of image sensors.

### Background

Image sensors have become ubiquitous. They are widely used in digital still cameras, cellular phones, security cameras, as well as medical, automotive, and other applications. The technology for manufacturing image sensors continues to advance at a great pace. For example, the demands for higher image sensor resolution and lower power consumption motivate further miniaturization and integration of image sensors into digital devices.

Image sensors operate in response to image light coming from an external scene and being incident upon the image sensor. An image sensor includes an array of pixels having photosensitive elements (e.g., photodiodes) that absorb a portion of the incident image light and in response generate corresponding electrical charge. The electrical charge of individual pixels may be measured as an output voltage of each photosensitive element.

In general, the output voltage varies as a function of the intensity and duration of the incident light. The output voltage of individual photosensitive elements is used to produce a digital image (i.e., image data) representing an external scene.

In some applications, image sensors are event-based vision sensors (EVS). EVS pixels are typically characterized by the application of a controlled temporal contrast step. One can then observe the probability of an event as well as the latency and its random distribution from a contrast change to when the circuit detects said latency. In either case—given the probabilistic nature of both event trigger probabilities and time-stamp distributions, measurements may need to be performed several times to yield reliable sample statistics. Wafer testing may have a significant impact on the cost of a product.

Thus, measuring events trigger probabilities or time-stamp distributions as a function of temporal contrast change can be undesirable. Accordingly, methods for fast and efficient testing EVS are needed.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a conventional event-based vision sensor (EVS).

FIG. 2A is an example EVS, in accordance with an embodiment of the present disclosure.

FIG. 2B is another example EVS, in accordance with an embodiment of the present disclosure.

FIG. 3 is a graph of example bitline (BL) outputs, in accordance with an embodiment of the present disclosure.

FIG. 4A is an example first buffer, in accordance with an embodiment of the present disclosure.

FIG. 4B is a graph of an example electronic contrast step, in accordance with an embodiment of the present disclosure.

FIG. 5A is an example difference detector, in accordance with an embodiment of the present disclosure.

FIG. 5B is a graph of an example output of a first comparator and a second comparator, in accordance with an embodiment of the present disclosure.

FIG. 5C is another example difference detector, in accordance with an embodiment of the present disclosure.

FIG. 5D is a graph of an example output of a first comparator and a second comparator, in accordance with an embodiment of the present disclosure.

FIG. 6 is an example method of testing an EVS, in accordance with an embodiment of the present disclosure.

FIG. 7 is an example method of testing a performance of a front end of an EVS, in accordance with an embodiment of the present disclosure.

FIG. 8 is an example method of testing a performance of a difference detector of an EVS, in accordance with an embodiment of the present disclosure.

FIG. 9 is an example method of testing a performance of a first comparator and a second comparator of an EVS, in accordance with an embodiment of the present disclosure.

FIG. 10 is another example method of testing a performance of a first comparator and a second comparator of an EVS, in accordance with an embodiment of the present disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

Event-based vision sensors (EVS), and in particular, methods for testing the performance of EVC are disclosed. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

From the foregoing, it will be appreciated that specific embodiments of the technology have been described herein for purposes of illustration, but that various modifications may be made without deviating from the disclosure. Moreover, while various advantages and features associated with certain embodiments have been described above in the context of those embodiments, other embodiments may also exhibit such advantages and/or features, and not all embodiments need necessarily exhibit such advantages and/or features to fall within the scope of the technology. Where methods are described, the methods may include more, fewer, or other steps. Additionally, steps may be performed in any suitable order. Accordingly, the disclosure can encompass other embodiments not expressly shown or described herein. In the context of this disclosure, the terms “about,” “approximately,” etc., mean +/−5% of the stated value.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

Briefly, the embodiments of the present technology are directed to testing the performance of multiple components of an EVS. In some embodiments, a front-end of an EVS (such as a first buffer, logarithmic amplifier, and/or source as described herein) is tested to ensure proper performance (i.e., that the front-end of the EVS is functioning properly). In some embodiments, one or more outputs of a bitline (BL) are used to determine performance of the front-end. In some embodiments, a row-select transistor or a second buffer is coupled to the BL. In some embodiments, a performance of a difference detector of the EVS may also be tested independently or sequentially to testing the performance of the front-end of the EVS. In some embodiments, independently or sequentially to testing the performance of the front-end and/or difference detector, a performance of a first comparator and a second comparator of the EVS may be tested. As a result, the test results of the photodiode itself can be obtained faster and more accurately.

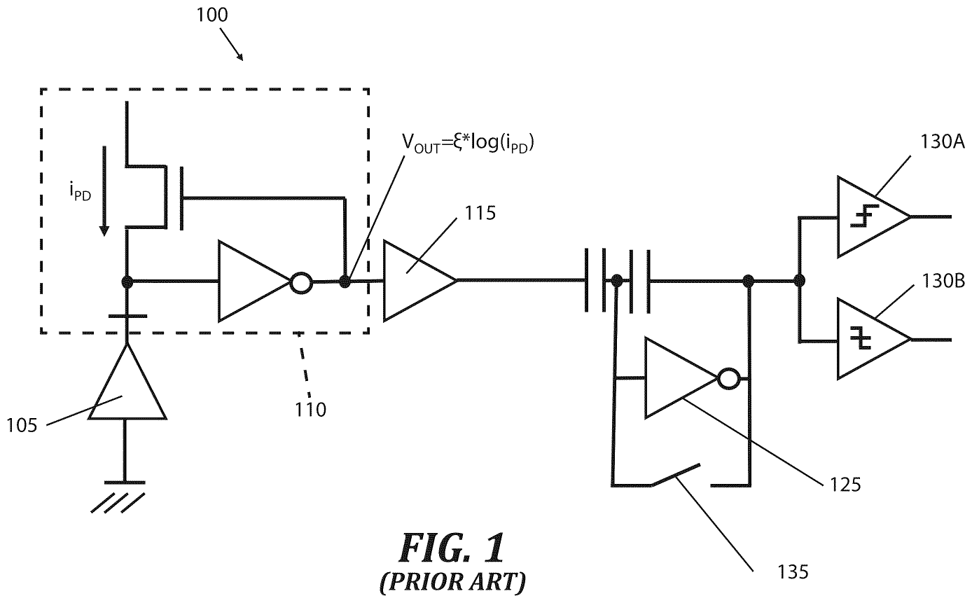

FIG. 1 is a conventional event-based vision sensor (EVS) 100. The EVS 100 may include a photodiode 105, a logarithmic amplifier 110, a first buffer 115, a difference detector 125 having a reset switch 135, a first comparator 130A, and a second comparator 130B.

The output of the logarithmic amplifier 110 (V_{OUT}=ξ*log(i_{PD})) is typically buffered by the first buffer 115 and fed into the difference detector 125. The difference detector 125 then feeds into the first comparator 130A, or the second comparator 130B, based on one or more predetermined thresholds. Generally, EVS (also referred to herein as “EVS pixels”) such as EVS 100 create events if a log intensity exceeds one or more predetermined thresholds. The output of the EVS either yields +1 (i.e., an increase in intensity), −1 (i.e., a decrease of intensity, or 0 (i.e., a change below thresholds).

Such pixels are typically characterized by the application of a controlled temporal contrast step. One can then observe the probability of an event as well as the latency and its random distribution from a contrast change to when the circuit detects said latency. As explained herein, given the probabilistic nature of both event trigger probabilities and time-stamp distributions, measurements are performed several times to yield reliable sample statistics. This can result in a high cost of testing, in both money and time.

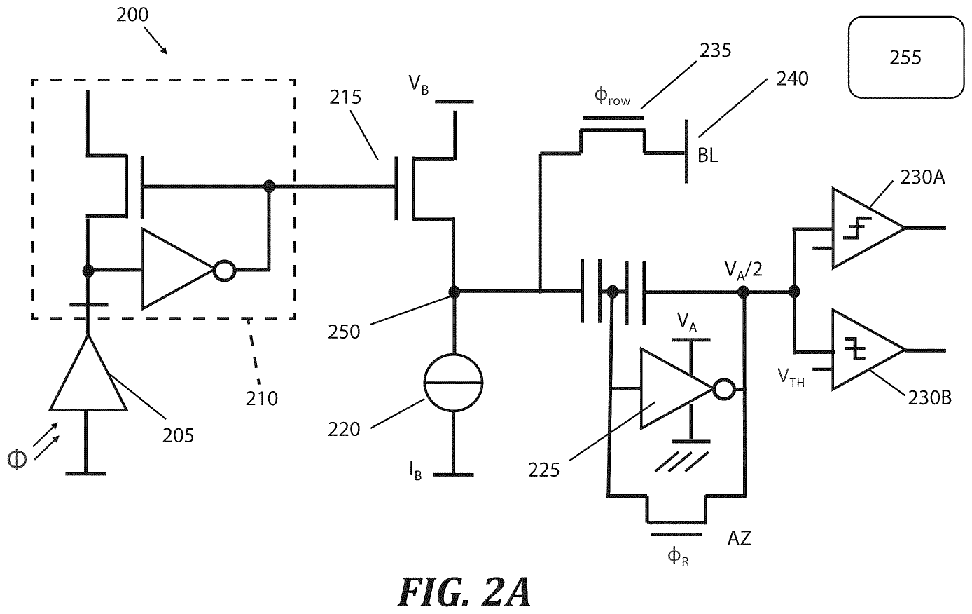

FIG. 2A is an example EVS 200, in accordance with an embodiment of the present disclosure. In some embodiments, the EVS 200 includes a photodiode 205, a logarithmic amplifier 210, a first buffer 215, a source 220, a difference detector 225, a first comparator 230A, a second comparator 230B, a row-select transistor 235, a bitline (BL) 240, a source follower 250, and an analog-to-digital converter (ADC) 255. It is desirable to measure a voltage of the analog front end (or specifically the logarithmic amplifier 210), the difference detector 225, and the comparators (i.e., the first comparator 230A and the second comparator 230B) separately to ensure proper operation (i.e., to determine a performance of each). Doing so in an analog manner (i.e., by probing a bitline with an ADC) avoids the need to measure time-consuming triggering probabilities of successive temporal contrast steps.

In some embodiments, the logarithmic amplifier 210, the first buffer 215, the source 220, and the source follower 250 may be referred to herein, collectively, as the “front-end” of the EVS 200. In some embodiments, the row-select transistor 235 is coupled to an output of the front-end (i.e., an output of the logarithmic amplifier 210, the source follower 250, and/or the first buffer 215). In some embodiments, the row-select transistor 235 feeds into the BL 240. In some embodiments, the EVS 200 may include a BL 240 but not a row-select transistor 235 (as shown and described in FIG. 2B). In some embodiments, an ADC 255 may probe the BL 240 to monitor one or more outputs of the BL 240. In some embodiments, the ADC 255 may be implemented in a column-parallel manner, and it may be an ADC for an active pixel circuit (APS), such as a complementary metal oxide semiconductor (CMOS) image sensor (CIS).

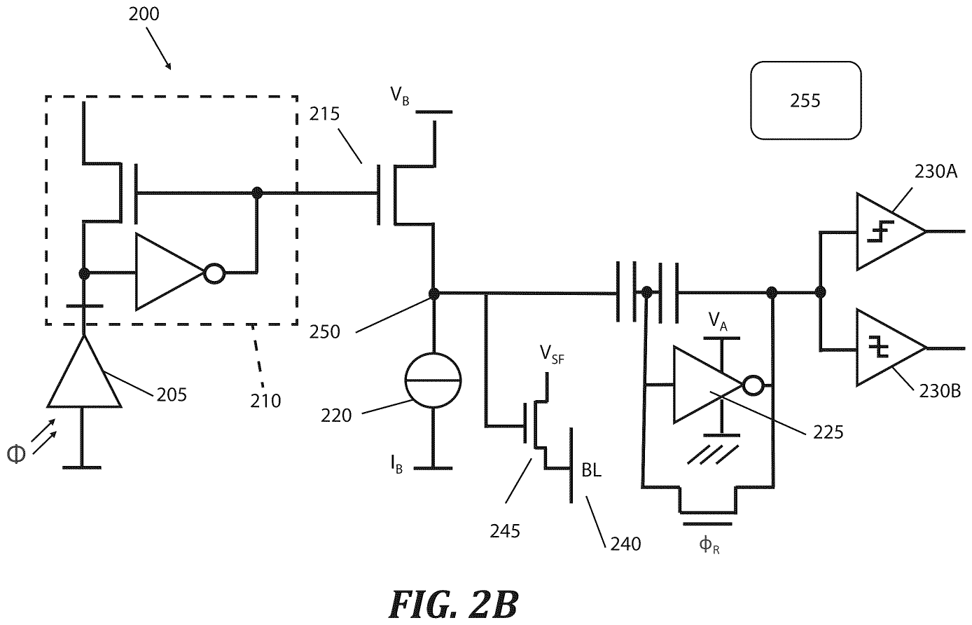

In operation, the photodiode 205 (or generally, a “pixel array” of the EVS) may be irradiated by sweeping irradiance Φ. The output of the front end (i.e., the logarithmic amplifier 210, the first buffer 215, the source 220, and the source follower 250) (or generally the “pixel array”), may then be fed into the BL 240. The BL 240 may be probed with the ADC 255. One or more outputs of the BL 240 are then monitored, as further shown and explained below in FIG. 3. The one or more outputs of the BL 240 may then be evaluated to determine the performance of the front-end (or more specifically, the performance of the logarithmic amplifier 210) as explained in detail in FIG. 3.

Further, the EVS 200 may also be used to evaluate a performance of the difference detector 225. In some embodiments, the performance of the difference detector 225 may be conducted independently of any other component of the EVS 200. In some embodiments, the performance of the difference detector 225 may be evaluated after evaluating the front-end of the EVS 200.

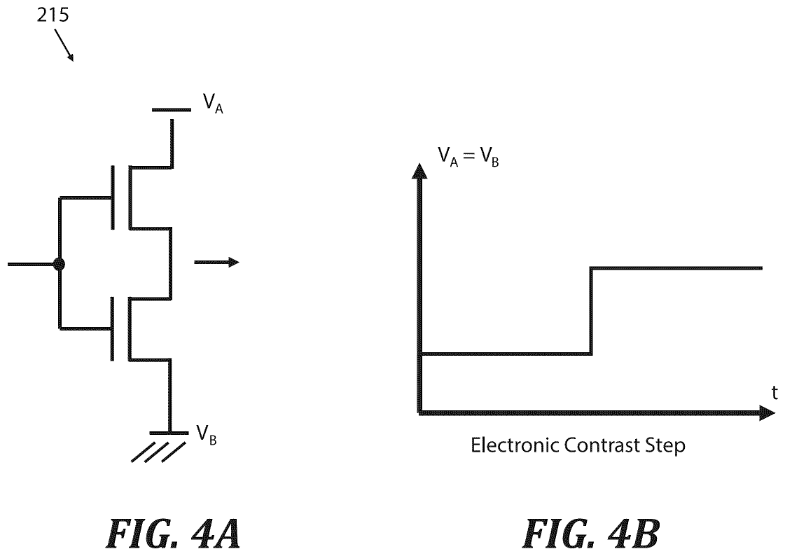

A ramp signal may be generated by merging the positive and negative supply of the inverting buffer utilized in the feedback branch of the difference detector 225. The sweeping and/or ramping of both rails jointly results in a ramp at the input of the comparators (i.e., the first comparator 230A and the second comparator 230B). In order to avoid additional uncontrolled and/or undesired signal change at the input of the comparators, the front-end of the EVS 200 may be forced to a static level. In some embodiments, forcing the front end of the EVS 200 to a static level includes disabling the logarithmic amplifier 210. In other embodiments, forcing the front end of the EVS 200 to a static level includes disabling the first buffer 215. In other embodiments, forcing the front end of the EVS 200 to a static level includes disabling a bias current of a source 220 of the EVS 200 when the first buffer 215 is current starved. The bias current can be disabled such that the output will be pulled to either supply rail (as shown in FIGS. 5A-5D) depending on whether the current is starved on high or low side. In some embodiments, a swept voltage is injected to the difference detector 225 with the BL 240. The output of the EVS 200 (i.e., the output of the first comparator 230A and the second comparator 230B) may be monitored relative to a voltage threshold. Further, an event may be detected when the output of the EVS switches from the first comparator 230A to the second comparator 230B based on the voltage threshold, as shown and explained in detail in FIGS. 5A-5D. In some embodiments, the measurement may be executed for one or various comparator threshold settings. During a pass/fail evaluation, the trigger threshold for any probed configuration can be determined whether the monitored output of the first comparator 230A, the second comparator 230B, or both fall into desired bounds.

In some embodiments, determining a performance of the difference detector further comprises forcing the difference detector 225 into an auto-zero phase with a reset switch (such as reset switch 135). In some embodiments, a ramp signal may be generated without merging positive and negative supply of the inverting feedback amplifier of the difference detector 225. Instead, a reset switch (such as reset switch 135) of the difference detector 225 can be used to force the inverting amplifier into an auto-zero phase where the input equals the output. If the devices are designed symmetrically the output will go to V_{DD}/2. Now sweeping solely VDD, a ramp signal can be generated. Again, the front-end of the EVS 200 should be kept static, as explained above. Multiple thresholds may be evaluated and for each measurement it is to be determined whether a given comparator (i.e., first comparator 230A or second comparator 230B) or the difference detector 225 performs within desired bounds.

Further, the EVS 200 may also be used to evaluate performance of the first comparator 230A and the second comparator 230B. In some embodiments, the performance of the first comparator 230A and the second comparator 230B may be evaluated independently of any other component of the EVS 200. For example, the performance of the first comparator 230A and the second comparator 230B may be evaluated after evaluating the front-end of the EVS 200 and/or the performance of the difference detector 225. To measure the threshold and operation of the comparators (i.e., first comparator 230A and second comparator 230B) it is desirable to sweep/ramp an input signal synchronously to a counter operation. The trigger threshold can then be indirectly measured through the count level at which a trigger occurred.

In operation, determining a performance of the first comparator and the second comparator may include driving a signal with the BL 240, and determining the threshold voltage V_{TH} of the first comparator 230A and the second comparator 230B. In some embodiments, the signal is a ramp signal, a monotonic portion of a sinusoidal signal, non-linear monotonic ramp signal, step response signal, or a combination thereof. In order to assess the proper operation (e.g., gain) a time-varying input signal should be generated. One way to realize such signal is to use the row-select transistor 235. Here, for a given row the row-select transistor 235 may be activated. Instead of probing a signal on the BL 240, the BL 240 is actively driven to realize a signal (such as a ramp signal). Synchronously to the signal, a counter may be operated to determine the time-point at which the signal amplified by the difference detector 225 would push the comparators (i.e., first comparator 230A and the second comparator 230B) to trigger (i.e., to output a voltage), as shown and described in FIG. 5B. Again, it can then be determined whether the gain falls into expected bounds, as shown and described in FIGS. 5A-5B.

FIG. 2B is another example EVS 200, in accordance with an embodiment of the present disclosure. In some embodiments, the EVS 200 includes a photodiode 205, a logarithmic amplifier 210, a first buffer 215, a source 220, a difference detector 225, a first comparator 230A, a second comparator 230B, a second buffer 245, a bitline (BL) 240, a source follower 250, and an analog-to-digital converter (ADC) (such as ADC 255 in FIG. 2A). In some embodiments, the second buffer 245 may be utilized instead of a row-select transistor (such as row-select transistor 235 of FIG. 2A) to feed the output of the front end (i.e., the logarithmic amplifier 210, the first buffer 215, the source 220, and the source follower 250) (or generally the “pixel array”) to the BL.

In operation, the photodiode 205 (or generally, a pixel array of the EVS 200) may be irradiated by sweeping irradiance Φ. The output of the front end, may then be fed into the BL 240 with the second buffer 245. The supply of the second buffer 245 may be driven in a row-wise manner. Second buffers 245 of a particular column may share voltage off a given BL 240. Only one second buffer 245 may receive a positive supply (V_{SF}) at any given time such that the BL 240 is driven essentially only by said row (mimicking row-select behavior through power supply V_{SF} modulation). The BL 240 may be probed with the ADC 255. One or more outputs of the BL 240 are then monitored, as shown in FIG. 3. The one or more outputs of the BL 240 may then determine the performance of the front-end (or more specifically, the logarithmic amplifier 210) as explained in detail in FIG. 3.

Further, the EVS 200 may also be used to evaluated a performance of the difference detector 225. In some embodiments, the performance of the difference detector 225 may be conducted independently of any other component of the EVS 200. In some embodiments, the performance of the difference detector 225 may be evaluated after evaluating the front-end of the EVS 200.

Further, the EVS 200 may also be used to evaluate a performance of the first comparator 230A and the second comparator 230B. In some embodiments, the performance of the first comparator 230A and the second comparator 230B may be conducted independently of any other component of the EVS 200. In some embodiments, the performance of the first comparator 230A and the second comparator 230B may be evaluated after evaluating the front-end of the EVS 200 and/or the performance of the difference detector 225.

In some embodiments, determining the performance of the first comparator 230A and the second comparator 230B includes merging positive and negative rails of the first buffer 215, injecting a signal with the first buffer 215, monitoring an output the EVS 200 relative to a voltage threshold, and detecting an event when the output of the EVS 200 switches from the first comparator 230A to the second comparator 230B based on the voltage threshold. In some embodiments, the signal injected to the first buffer 215 is a ramp signal, a monotonic portion of a sinusoidal signal, non-linear monotonic ramp signal, step response signal, or a combination thereof.

In some embodiments, determining the performance of the first comparator and the second comparator includes disabling the logarithmic amplifier 210, forcing an input of the first buffer 215 to be static, monitoring an output of the first comparator 230A or an output of the second comparator 230B relative to a voltage threshold, and detecting an event (as shown in FIG. 5D) when an output of the EVS 200 switches from the first comparator 230A to the second comparator 230B based on the voltage threshold.

FIG. 3 is a graph of an example bitline (BL) outputs (such as BL 240 in FIGS. 2A-2B), in accordance with an embodiment of the present disclosure. In some embodiments, the outputs plotted in FIG. 3 may be outputs from the BL 240 of either FIG. 2A or FIG. 2B.

On the horizontal axis is irradiance Φ. On the vertical axis is the signal fed to the BL Φ_{row}. In some embodiments, the signal Φ_{row} is fed to the BL through a row-select transistor (such as row-select transistor 235). In some embodiments, the signal Φ_{row} is fed to the BL through a second buffer (such as second buffer 245). FIG. 3 shows outputs of a BL of an EVS where a front-end of the EVS is operational, that is, having a good (or “acceptable”) performance. As used herein, “good” or “acceptable” performance is defined as the specific component being operational and in working order. In some embodiments, “good” or “acceptable” performance is a performance level adequate enough for sale and/or proper operation of the component of the EVS.

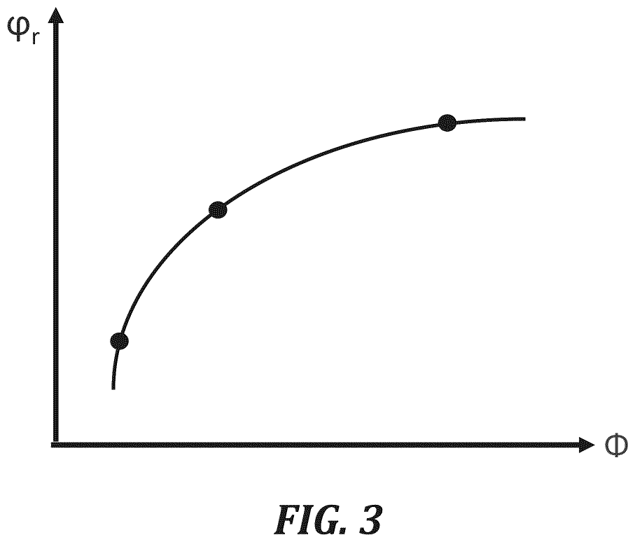

FIG. 4A is an example first buffer 215, in accordance with an embodiment of the present disclosure. In some embodiments, the first buffer 215 includes two transistors. A positive rail V_{A} and a negative rail V_{B} can be biased separately from other circuitry of the EVS. In some embodiments, the first buffer 215 may be used to force an input signal, such as when a performance of the comparators is being determined. If the first buffer 215 between a logarithmic amplifier (such as logarithmic amplifier 210) and a difference detector (such as difference detector 225) is implemented in a manner that its positive (V_{A}) and negative rail (V_{B}) can be biased separately from other pixel circuitry, then they can be operated at V_{DD}/GND during normal operation but joined during a wafer level test. If a reference level of the first buffer 215 is high, it can be determined that the output of the first buffer 215 tracks V_{A}=V_{B}. The application of an electronic temporal contrast step on the positive and negative rails allows for probing the contrast threshold electronically rather than optically, as shown in FIG. 4B.

FIG. 4B is a graph of an example electronic contrast step, in accordance with an embodiment of the present disclosure. On the vertical axis is the output of the first buffer 215 where V_{A}=V_{B}. On the horizontal axis is time. As shown, an electronic contrast step is observed. As explained herein, determining the performance of the first comparator 230A and the second comparator 230B may include merging positive (V_{A}) and negative rails (V_{B}) of the first buffer 215, injecting a signal with the first buffer 215, monitoring an output the EVS 200 relative to a voltage threshold, and detecting an event when the output of the EVS 200 switches from the first comparator 230A to the second comparator 230B based on the voltage threshold.

FIG. 5A is an example difference detector 225, in accordance with an embodiment of the present disclosure. In some embodiments, if the amplifier in the feedback path of the difference detector 225 is implemented in a manner that its positive rail (V_{C}) and negative rail (V_{D}) can be operated separately from the remaining pixel circuitry, during operation V_{C} could be driven at V_{DD} and V_{D} at GND. During the wafer test V_{C}=V_{D} could be chosen so that the output of the difference detector 225, which equals the input of the comparator stages can be driven in analog manner. For example, a ramp signal may be applied during the wafer test and a counter could measure the time between a ramp start and triggering level of the comparators (such as first comparator 230A and second comparator 230B). Alternatively, additional switches or multiplexers may be employed to directly feed in analog levels into the difference detector circuit and/or the comparator circuits.

FIG. 5B is a graph of an example output of a first comparator and a second comparator, in accordance with an embodiment of the present disclosure. On the vertical axis is the output of the difference detector 225, where V_{C}=V_{D}. On the horizontal axis is time. Also shown on the horizontal axis a counter signal represented as a sinusoid. Each peak of the sinusoid represents a count of the counter signal. A comparator threshold TH is illustrated as a dashed line. The offset O may be measured to determine performance of the comparators (such as first comparator 230A and second comparator 230B).

FIG. 5C is another example difference detector 225, in accordance with an embodiment of the present disclosure. In some embodiments, the difference detector 225 may be autozeroed, such as when a performance of the comparators (such as first comparator 230A and second comparator 230B) is determined. In such embodiments, a ramp signal may be generated without merging positive and negative supply of the inverting feedback amplifier of the difference detector 225. Instead, the reset switch of the difference detector can be used to force the inverting amplifier into an auto-zero phase where the input equals the output. If the devices are designed symmetrically the output will go to V_{DD}/2. By sweeping V_{DD}, a ramp signal can be generated.

FIG. 5D is a graph of an example output of a first comparator and a second comparator, in accordance with an embodiment of the present disclosure. The voltage threshold TH is shown as the dashed line. As explained in FIG. 5C, when the output of the difference detector is V_{A}/2, the output of the difference detector is equal to the threshold TH. If the comparators are operational (i.e., the performance is “good” and/or “acceptable”), an event may be detected when the output of the difference detector is at the threshold TH. If the output of the difference detector is V_{A}/2, assuming the comparators are operational, the event is detected.

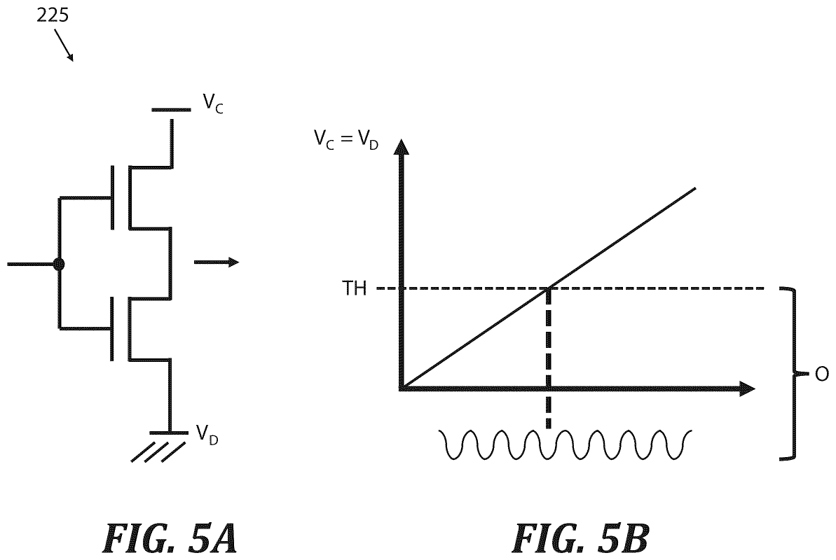

FIG. 6 is an example method 600 of evaluating an EVS, in accordance with an embodiment of the present disclosure. In some embodiments, the method 600 is carried out with an EVS (such as EVS 200), having a photodiode (such as photodiode 205), a logarithmic amplifier (such as logarithmic amplifier 210), a first buffer (such as first buffer 215), a source (such as source 220), a difference detector (such as difference detector 225), a first comparator (such as first comparator 230A), a second comparator (such as second comparator 230B), a bitline (BL) (such as BL 240), and a source follower (such as source follower 250). In some embodiments, the EVS may include a row-select transistor (such as row-select transistor 235) or a second buffer (such as second buffer 245).

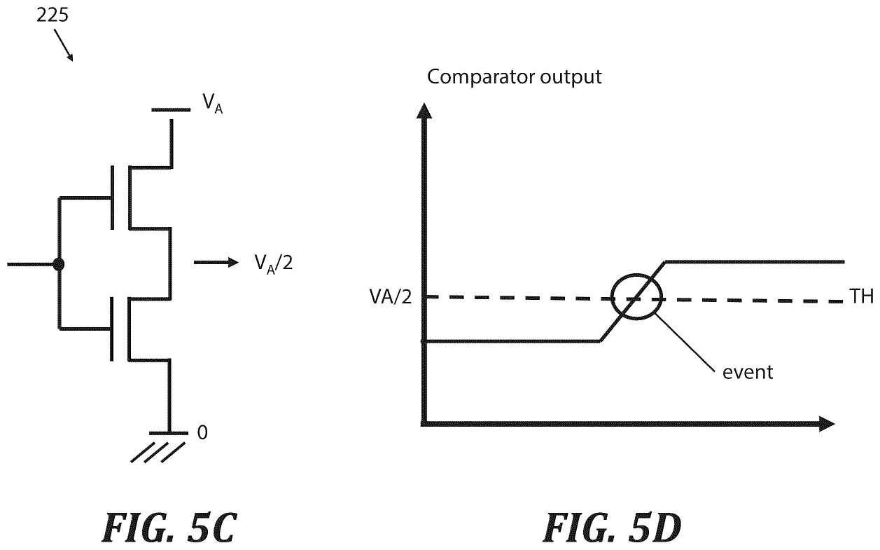

In block 605, a performance of a front end of the EVS is determined. In some embodiments, the front end of the EVS includes the logarithmic amplifier, the first buffer, the source, and/or the source follower. In some embodiments, the performance of the front end of the EVS may be determined with method 700, as described in FIG. 7.

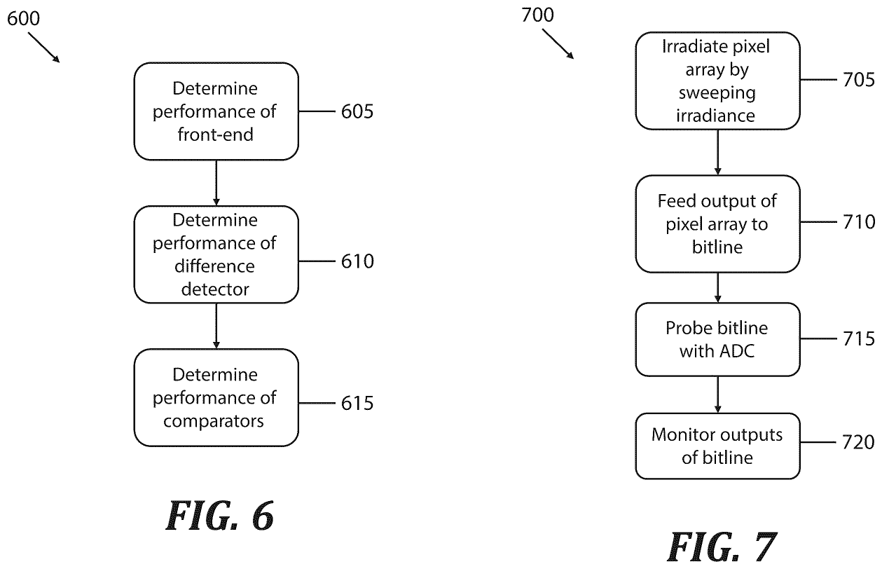

In block 610, a performance of the difference detector is determined. In some embodiments, the performance of the difference detector may be determined with method 800 as described in FIG. 8.

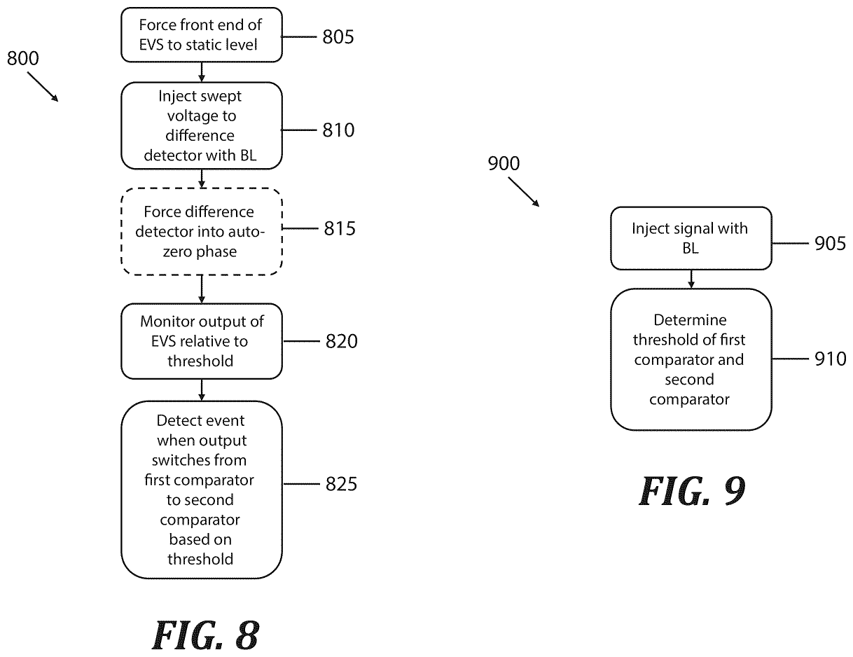

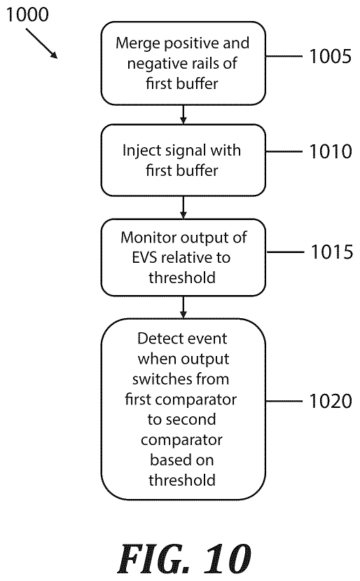

In block 615, a performance of the comparators (such as the first comparator and the second comparator) is determined. In some embodiments, the performance of the comparators may be determined with methods 900 and/or 1000 as described in FIGS. 9-10, respectively.

FIG. 7 is an example method 700 of evaluating a performance of a front end of an EVS, in accordance with an embodiment of the present disclosure. In some embodiments, the method 700 is carried out with an EVS (such as EVS 200), having a photodiode (such as photodiode 205), a logarithmic amplifier (such as logarithmic amplifier 210), a first buffer (such as first buffer 215), a source (such as source 220), a difference detector (such as difference detector 225), a first comparator (such as first comparator 230A), a second comparator (such as second comparator 230B), a bitline (BL) (such as BL 240), and a source follower (such as source follower 250). In some embodiments, the EVS may include a row-select transistor (such as row-select transistor 235) or a second buffer (such as second buffer 245). The method 700 may be performed as a step of the method 600.

In block 705, a pixel array of the EVS is irradiated by sweeping irradiance (such as irradiance Φ).

In block 710, an output of the pixel array, in response to the irradiance, is fed to the bitline (BL). In some embodiments, the output may be fed to the BL with a row-select transistor (such as shown in FIG. 2A). In some embodiments, the output may be fed to the BL with a second buffer (as shown in FIG. 2B).

In block 715, the BL is probed with an analog to digital convertor (ADC) (such as ADC 255). In some embodiments, the ADC In some embodiments, the ADC 255 may be implemented in a column-parallel manner, and it may be an ADC for an active pixel circuit (APS), such as a complementary metal oxide semiconductor (CMOS) image sensor (CIS).

In block 720, outputs of the BL are monitored. In some embodiments, the outputs of the BL determine if the front-end of the EVS is operational (i.e., if the performance is “good” and/or “acceptable”). An example of “good” and/or “acceptable” performance of the front end is shown in FIG. 3.

FIG. 8 is an example method 800 of evaluating a performance of a difference detector of an EVS, in accordance with an embodiment of the present disclosure. In some embodiments, the method 800 is carried out with an EVS (such as EVS 200), having a photodiode (such as photodiode 205), a logarithmic amplifier (such as logarithmic amplifier 210), a first buffer (such as first buffer 215), a source (such as source 220), a difference detector (such as difference detector 225), a first comparator (such as first comparator 230A), a second comparator (such as second comparator 230B), a bitline (BL) (such as BL 240), and a source follower (such as source follower 250). In some embodiments, the EVS may include a row-select transistor (such as row-select transistor 235) or a second buffer (such as second buffer 245). The method 800 may be performed as a step of the method 600. Further, in some embodiments, the method 800 may be performed after method 700.

In block 805, the front end of the EVS is forced to a static level. In some embodiments, forcing the EVS to the static level includes disabling the logarithmic amplifier. In some embodiments, forcing the front end of the EVS to a static level includes disabling the first buffer. In some embodiments, forcing the front end of the EVS to a static level includes disabling a bias current of a source of the EVS when the first buffer is current starved.

In block 810, a swept voltage is injected to the difference detector with the BL. In some embodiments, the BL is coupled to a row-select transistor. In such embodiments, the BL may inject a swept voltage to the difference detector.

Optionally, in block 815, the difference detector is forced into an auto-zero phase, as shown and described in FIGS. 5C-5D.

In block 820, an output of the EVS is monitored relative to a voltage threshold of the first comparator and the second comparator. In some embodiments, an event is detected when the output meets the voltage threshold. In embodiments, where the difference detector is forced to the auto-zero phase, an event is detected if the difference detector is operational (i.e., if performance is “good” or “acceptable”).

In block 825, an event is detected when the output of the EVS switches from the first comparator to the second comparator based on the voltage threshold, as shown in FIG. 5D.

FIG. 9 is an example method 900 of evaluating a performance of a first comparator and a second comparator of an EVS, in accordance with an embodiment of the present disclosure. In some embodiments, the method 900 is carried out with an EVS (such as EVS 200), having a photodiode (such as photodiode 205), a logarithmic amplifier (such as logarithmic amplifier 210), a first buffer (such as first buffer 215), a source (such as source 220), a difference detector (such as difference detector 225), a first comparator (such as first comparator 230A), a second comparator (such as second comparator 230B), a bitline (BL) (such as BL 240), and a source follower (such as source follower 250). In some embodiments, the EVS may include a row-select transistor (such as row-select transistor 235) or a second buffer (such as second buffer 245). The method 900 may be performed as a step of the method 600. Further, in some embodiments, the method 900 may be performed after method 800.

In block 905, a signal is injected with the BL. In some embodiments, the EVS includes a row-select transistor, which allows the BL to inject the signal. In some embodiments, the signal is a ramp signal, a monotonic portion of a sinusoidal signal, non-linear monotonic ramp signal, step response signal, or a combination thereof.

In block 910, a threshold of the first comparator and the second comparator is determined based on the signal injected by the BL. In this manner, the performance of the first comparator and the second comparator may be determined.

FIG. 10 is another example method 1000 of evaluating a performance of a first comparator and a second comparator of an EVS, in accordance with an embodiment of the present disclosure. In some embodiments, the method 1000 is carried out with an EVS (such as EVS 200), having a photodiode (such as photodiode 205), a logarithmic amplifier (such as logarithmic amplifier 210), a first buffer (such as first buffer 215), a source (such as source 220), a difference detector (such as difference detector 225), a first comparator (such as first comparator 230A), a second comparator (such as second comparator 230B), a bitline (BL) (such as BL 240), and a source follower (such as source follower 250). In some embodiments, the EVS may include a row-select transistor (such as row-select transistor 235) or a second buffer (such as second buffer 245). The method 1000 may be performed as a step of the method 600. Further, in some embodiments, the method 1000 may be performed after method 800.

In block 1005, a positive rail and a negative rail of the first buffer may be merged, as shown in FIGS. 4A-4B.

In block 1010, a signal may be injected with the first buffer. In some embodiments, the signal is a ramp signal, a monotonic portion of a sinusoidal signal, non-linear monotonic ramp signal, step response signal, or a combination thereof. In some embodiments, this is done as an alternative to injecting the signal with the BL via a row-select transistor. In such embodiments, the BL may be coupled to a second buffer as opposed to a row-select transistor.

In block 1015, an output of the EVS is monitored relative to a voltage threshold of the first comparator and the second comparator.

In block 1020, an event is detected when the output of the EVS switches from the first comparator to the second comparator based on the voltage threshold, as shown in FIG. 5D.

It should be understood that all methods 600, 700, 800, 900, and 1000 should be interpreted as merely representative. In some embodiments, process blocks of all methods 600, 700, 800, 900, and 1000 may be performed simultaneously, sequentially, in a different order, or even omitted, without departing from the scope of this disclosure.

What is claimed is:

1. A method for wafer testing an event-based vision sensor (EVS), the EVS sensor comprising a photodiode, a logarithmic amplifier configured to generate an amplified signal in response to voltage received by the photodiode, a first buffer, and a bitline (BL), the method comprising:
determining a performance of the logarithmic amplifier, wherein determining the performance comprises:
irradiating a pixel array by sweeping irradiance;
feeding an output of the pixel array into the BL;
probing one or more output of the BL with an analog-to-digital converter (ADC); and
monitoring the one or more outputs of the BL, wherein the performance is determined based upon the one or more outputs of the BL.

2. The method of claim 1, wherein the output of the pixel array is fed to the BL with a row-select transistor.

3. The method of claim 2, wherein the EVS further comprises a difference detector, a first comparator, and a second comparator, and wherein the method further comprises:
determining a performance of the difference detector, wherein determining the performance of the difference detector comprises:
forcing a front end of the EVS to a static level;
injecting a swept voltage to the difference detector with the BL;
monitoring an output the EVS relative to a voltage threshold; and
detecting an event when the output of the EVS switches from the first comparator to the second comparator based on the voltage threshold.

4. The method of claim 3, wherein forcing the front end of the EVS to the static level comprises disabling the logarithmic amplifier.

5. The method of claim 3, wherein forcing the front end of the EVS to the static level comprises disabling the first buffer.

6. The method of claim 3, wherein forcing the front end of the EVS to the static level comprises disabling a bias current of a source of the EVS when the first buffer is current starved.

7. The method of claim 3, wherein determining the performance of the difference detector further comprises forcing the difference detector into an auto-zero phase with a reset switch.

8. The method of claim 3, further comprising:
determining a performance of the first comparator and the second comparator, wherein determining the performance of the first comparator and the second comparator comprises:
driving a signal with the BL; and
determining the threshold of the first comparator and the second comparator.

9. The method of claim 8, wherein the signal is a ramp signal, a monotonic portion of a sinusoidal signal, a non-linear monotonic ramp signal, a step response signal, or a combination thereof.

10. The method of claim 1, wherein the output of the pixel array is fed to the BL with a second buffer.

11. The method of claim 10, wherein the EVS further comprises a difference detector, a first comparator, and a second comparator, wherein the method further comprises:
determining a performance of the first comparator and the second comparator, wherein determining the performance of the first comparator and the second comparator comprises:
merging positive and negative rails of the first buffer;
injecting a signal with the first buffer;
monitoring an output the EVS relative to a voltage threshold; and
detecting an event when the output of the EVS switches from the first comparator to the second comparator based on the voltage threshold.

12. The method of claim 11, wherein the signal is a ramp signal, a monotonic portion of a sinusoidal signal, a non-linear monotonic ramp signal, a step response signal, or a combination thereof.

13. The method of claim 10, wherein the EVS further comprises a difference detector, a first comparator, and a second comparator, wherein the method further comprises:
determining a performance of the first comparator and the second comparator, wherein determining the performance of the first comparator and the second comparator comprises:
disabling the logarithmic amplifier;
forcing an input of the first buffer to be static.
monitoring an output of the first comparator or an output of the second comparator relative to a voltage threshold; and
detecting an event when an output of the EVS switches from the first comparator to the second comparator based on the voltage threshold.

14. A method of determining a performance of a difference detector of an event-based vision sensor (EVS), the EVS sensor comprising a photodiode, a logarithmic amplifier configured to generate an amplified signal in response to voltage received by the photodiode, a first buffer, a bitline (BL), a difference detector, a first comparator, and a second comparator, and wherein the method comprises:
forcing a front end of the EVS to a static level;
injecting a swept voltage to the difference detector with the BL;
monitoring an output the EVS relative to a voltage threshold; and
detecting an event when the output of the EVS switches from the first comparator to the second comparator based on the voltage threshold.

15. The method of claim 14, wherein forcing the front end of the EVS to the static level comprises disabling the logarithmic amplifier, disabling the first buffer, or when the first buffer is current starved, disabling a bias current of a source of the EVS.

16. The method of claim 14, wherein determining a performance of the difference detector, further comprises forcing the difference detector into an auto-zero phase with a reset switch.

17. A method of determining a performance of a first comparator and a second comparator of an event-based vision sensor (EVS), the EVS sensor comprising a photodiode, a logarithmic amplifier configured to generate an amplified signal in response to voltage received by the photodiode, a first buffer, a bitline (BL), a difference detector, the first comparator, and the second comparator, wherein the method comprises:
injecting a signal to the difference detector;
monitoring an output the EVS relative to a voltage threshold; and
detecting an event when the output of the EVS switches from the first comparator to the second comparator based on the voltage threshold.

18. The method of claim 17, wherein the EVS further comprises a row-select transistor coupled with the BL, and wherein injecting the signal comprises driving the signal with the BL.

19. The method of claim 17, wherein the EVS further comprises a second buffer coupled to the BL, and wherein injecting the signal comprises:
disabling the logarithmic amplifier;
merging a positive and negative rail of the first buffer;
forcing the second buffer to a static level; and
driving the signal with the first buffer.

20. The method of claim 17, wherein signal is a ramp signal, a monotonic portion of a sinusoidal signal, non-linear monotonic ramp signal, step response signal, or a combination thereof.
